(19) United States
(12) Patent Application Publication
(10) Pub. No.: US 2020/0321755 A1
(43) Pub. Date: Oct. 8, 2020

(54) Output-Programmed Vertical Cavity Surface Emitting Laser Array

(71) Applicant: RaySea Technology Inc., R&D, San Jose, CA (US)

(72) Inventors: Li WANG, Albuquerque, NM (US); NEINYI LI, Albuquerque, NM (US)

(21) Appl. No.: 16/843,830

(22) Filed: Apr. 8, 2020

Related U.S. Application Data
(60) Provisional application No. 62/831,175, filed on Apr. 8, 2019.

(51) Int. Cl. H01S 5/42; H01S 5/183

(52) U.S. Cl. CPC H01S 5/423; H01S 5/18338; H01S 5/18313

(57) ABSTRACT

A VCSEL array includes a plurality of VCSEL elements arranged in a programmed pattern defining a center portion and a peripheral edge portion. The interval distances between the VCSEL elements in the vicinity of the center portion and/or at the center portion are greater than the interval distances between the VCSEL elements close to the peripheral edge portion, such that the VCSEL array has a uniform power output.

### CROSS REFERENCE OF RELATED APPLICATION

This application is a non-provisional application that claims the benefit of priority under 35 U.S.C. § 119(e) to a provisional application, application No. 62/831,175, filed Apr. 8, 2019, which is incorporated herewith by references in their entities.

### BACKGROUND OF THE PRESENT INVENTION

### Field of Invention

The present invention relates to vertical-cavity surface emitting laser arrays that are constructed by a plurality of laser diodes, and more particularly to an output-programmed vertical-cavity surface emitting laser array, such as a 2-D vertical-cavity surface emitting laser array, that is formed by VCSEL elements at predefined position, intended to achieve programmed optical output regarding power distribution, spectral width, rise/fall-time, and etc.

### Description of Related Arts

Vertical Cavity Surface Emitting Lasers (VCSEL), and particularly VCSEL arrays, are important technology for application within a variety of markets, including but not limited to consumer, industrial, automotive, and medical industries. VCSEL arrays are attractive choices due to their low cost and power scalability, especially for high power applications such as long-range flash LiDAR (Light Detection and Ranging) and optical pumping. However, most conventional VCSEL arrays fail to attain desirable output properties, particularly in the power uniformity and overall divergence.

Referring to FIG. 1, a schematic view of a conventional “standard” 2-D VCSEL array is illustrated, wherein the VCSEL elements 1P, generally having a uniform lateral confinement size, are arranged in a close-packed manner that each two of them have a fixed element-to-element spacing therebetween. However, the VCSEL elements 1P in different regions of the array have various heat dissipation capabilities that, typically, those adjacent to the peripheral edge of the array have a better heat dissipating performance than those in the center portion thereof. Due to the non-uniform heat dissipation of the VCSEL elements 1P in the center and those close in the peripheral edge, the temperate is higher in the vicinity of the center portion of the array. In other words, there is a temperate descent gradient from the center portion of the array to the peripheral edge thereof. Therefore, lower power output and smaller divergence would be expected from those elements close to the center of the array.

How to achieve desirable output properties, particularly power uniformity and small overall divergence, have been a focus for these arrays. Different approaches, like fine-tuning epitaxial structure (to reduce thermal sensitivity) and thickening metal layers (to remove excessive heat), have been adopted to alleviate this problem. However, these approaches are not that effective, since it is difficult and costly to modify the epitaxial structure of the VCSEL element to reduce its thermal sensitivity, while thickening metal layers fails to remove excessive heat in a satisfying level but inevitably increases the overall cost of the VCSEL.

U.S. Pat. No. 8,247,252B2 also discloses a way to remove the temperature hotspot in the center region of the array by using increased spacing from the center to the edge of the array, so as to increase the overall output power and power density.

How to achieve desirable output properties, particularly power uniformity and smaller overall divergence, is still a very important issue in the VCSEL field. And as the application scenarios expands, other optical output properties like spectral width, speckle pattern, rise/fall-time, and etc., are demanding. Therefore, it is necessarily to promote a general scheme for improving the optical output properties of the VCSEL array.

In addition, laser beam properties from arrayed structures are determined by a number of factors. Temperature gradient caused by nonuniform heat removal in high current/power applications will lead to power and divergence nonuniformity from different emitting elements. Parasitic elements (resistor, capacitor and inductor) can create nonuniform current distribution and different transient response, which will lead to different rise-and-fall-time.

### SUMMARY OF THE PRESENT INVENTION

The invention is advantageous in that it provides an output-programmed VCSEL array which is capable of achieving desirable output properties by arranging the VCSEL elements thereof in a programmed pattern. In other words, the present invention provides an economic and easy-to-implement approach for the VCSEL array to meet the requirements of the optical output properties, particularly power uniformity.

Another advantageous of the present invention is to provide an output-programmed VCSEL array which is capable of satisfying the requirements for different optical output properties with merely one single epitaxial structure. Therefore, the packaging for the VCSEL elements of the VCSEL array is uniform and simplified.

Another advantageous of the present invention is to provide an output-programmed VCSEL array, wherein the VCSEL elements of the VCSEL array are arranged in a programmed pattern that the spacing between those elements with a relatively bad heat dissipation is increased, while the interval distance between those elements with a relatively better heat dissipating performance is decreased, in such a manner that the VCSEL array has a better uniform power output.

Another advantageous of the present invention is to provide an output-programmed VCSEL array, wherein the VCSEL elements of the VCSEL array are arranged in a programmed pattern to increase the spacing between the elements in the vicinity of the center portion of the array, and to gradually decrease the spacing close to the peripheral edge thereof, in such a manner that the VCSEL array has a better uniform power output.

Another advantageous of the present invention is to provide an output-programmed VCSEL array, wherein the VCSEL elements of the VCSEL array are arranged in a programmed pattern that those elements positioned in the vicinity of the center portion of the array has a greater power density than those close to the peripheral edge portion, while the spacing between the elements in the vicinity of the center portion of the array is greater than that of the elements close to the peripheral edge of the array, such that the VCSEL array has a better uniform power density.

Another advantageous of the present invention is to provide an output-programmed VCSEL array which is also capable of acquiring a better performance in resolving current crowding issues by configuring the VCSEL elements of the array in different lateral confinement shapes.

Another advantageous of the present invention is to provide an output-programmed VCSEL array which is capable of achieving better non-uniformity optical output parameters, such as greater divergence, and shorter rise/fall-time, by arranging the VCSEL elements with appropriate confinement sizes and shapes in appropriate positions based on the distribution requirements on power, wavelength, divergence, and etc.

Another advantageous of the present invention is to provide an output-programmed VCSEL array, wherein the confinement sizes and shapes of VCSEL elements and the positions of the VCSEL elements can be pre-defined with thermal/electro-magnetic simulation software and then determined during wafer processing DOE (Design of Experiment).

Another advantageous of the present invention is to provide a relatively simple solution to achieve programmed output parameters, including uniform or purposely non-uniform ones, for high power 2-D VCSEL arrays.

According to the present invention, the foregoing and other objects and advantages are attained by a VCSEL array comprising a plurality of VCSEL elements arranged in a programmed pattern defining a center portion and a peripheral edge portion, wherein the interval distances between the VCSEL elements in a vicinity of the center portion and/or at the center portion are greater than the interval distances between the VCSEL elements close to the peripheral edge portion, such that the VCSEL array has a uniform power output.

In one embodiment of the present invention, the VCSEL emitting elements are arranged at pre-defined locations. The lateral confinement sizes of the elements can be the same or different. Pre-defined locations can be first estimated with thermal/electro-magnetic simulation software and then decided during wafer processing DOE. The elements can have same or different spacing between each other. Also, lateral confinement shapes can be the same or different for all the elements in the same array.

In one embodiment of the present invention, the interval distances between the VCSEL elements are gradually decreased from the center portion to the peripheral edge portion of the VCSEL elements.

In one embodiment of the present invention, the VCSEL elements positioned in the vicinity of the center portion and/or at the center portion of the VCSEL elements have a greater power density than that of the VCSEL elements close to the peripheral edge portion, such that the VCSEL array has a uniform power density.

In one embodiment of the present invention, the output power of the VCSEL elements of the VCSEL array is gradually decreased from the center portion to the peripheral edge portion.

In one embodiment of the present invention, the lateral confinement size of the VCSEL elements in the vicinity of the center portion of the VCSEL elements is greater than that of the VCSEL elements close to the peripheral edge portion thereof, such that the VCSEL array has a uniform power density.

In one embodiment of the present invention, the lateral confinement sizes of the VCSEL elements are gradually decreased from the center portion of the VCSEL elements to the peripheral edge portion thereof.

In one embodiment of the present invention, the center portion of the VCSEL elements is defined at the geometry center portion of the VCSEL array, while the peripheral edge portion of the VCSEL elements is defined at the geometry peripheral edge portion of the VCSEL array.

In one embodiment of the present invention, the longitudinal interval distance between the VCSEL elements is greater than the transverse interval distance between the VCSEL elements.

In one embodiment of the present invention, the interval distance between each two elements is ranged from 18 microns to 200 microns.

In one embodiment of the present invention, the lateral confinement sizes of the VCSEL elements are ranged from 6 microns to 100 microns.

In one embodiment of the present invention, each VCSEL element has a circular lateral confinement shape.

In one embodiment of the present invention, each VCSEL element has an elliptical lateral confinement shape.

In one embodiment of the present invention, a portion of the VCSEL elements has a non-circular lateral confinement shape.

In one embodiment of the present invention, wherein each VCSEL element comprises a substrate, a first conducting layer electrically connected to the substrate at the bottom side thereof, a first metamorphic DBR epitaxially formed on the substrate, at least one light emitting portion epitaxially formed on the first metamorphic DBR, an oxide confining layer which is formed on the at least one light emitting portion and defines an oxide aperture, a second metamorphic DBR formed on the oxide confining layer while the at least one light emitting portion is sandwiched between the first metamorphic DBR and the second metamorphic DBR, and a second conducting layer which is electrically connected to the second metamorphic DBR and defines a light window aligning with the oxide aperture of the oxide confining layer.

Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a schematic view of a conventional “standard” 2-D VCSEL array.

FIG. 2 is a sectional schematic view of a VCSEL array according to a preferred embodiment of the present invention.

FIG. 3 is a schematic view illustrating an epitaxial structure of a VCSEL element of the VCSEL array according to the preferred embodiment of the present invention.

FIG. 4 is a schematic view illustrating a VCSEL array according to a first alternative mode of the preferred embodiment of the present invention.

FIG. 5 is a schematic view illustrating a VCSEL element of the VCSEL array according to second alternative mode of the preferred embodiment of the present invention

FIG. 6 is a schematic view illustrating a VCSEL element of the VCSEL array according to a third alternative mode of the preferred embodiment of the present invention.

FIG. 7 is a schematic view illustrating a VCSEL element of the VCSEL array according to a fourth alternative mode of the preferred embodiment of the present invention.

FIG. 8 is a schematic view illustrating a VCSEL element of the VCSEL array according to a fifth alternative mode of the preferred embodiment of the present invention.

FIG. 9 is a schematic view illustrating a VCSEL element of the VCSEL array according to a sixth alternative mode of the preferred embodiment of the present invention.

FIG. 10 is a schematic view illustrating a VCSEL element of the VCSEL array according to an seventh alternative mode of the preferred embodiment of the present invention.

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

Those skilled in the art should understand that, in the disclosure of the present invention, terminologies of “longitudinal,” “lateral,” “upper,” “front,” “back,” “left,” “right,” “perpendicular,” “horizontal,” “top,” “bottom,” “inner,” “outer,” and etc. just indicate relations of direction or position are based on the relations of direction or position shown in the appended drawings, which is only to facilitate descriptions of the present invention and to simplify the descriptions, rather than to indicate or imply that the referred device or element must apply specific direction or to be operated or configured in specific direction. Therefore, the above mentioned terminologies shall not be interpreted as confine to the present invention.

It is understandable that the term “a” should be understood as “at least one” or “one or more”. In other words, in one embodiment, the number of an element can be one and in other embodiment the number of the element can be greater than one. The term “a” is not construed as a limitation of quantity.

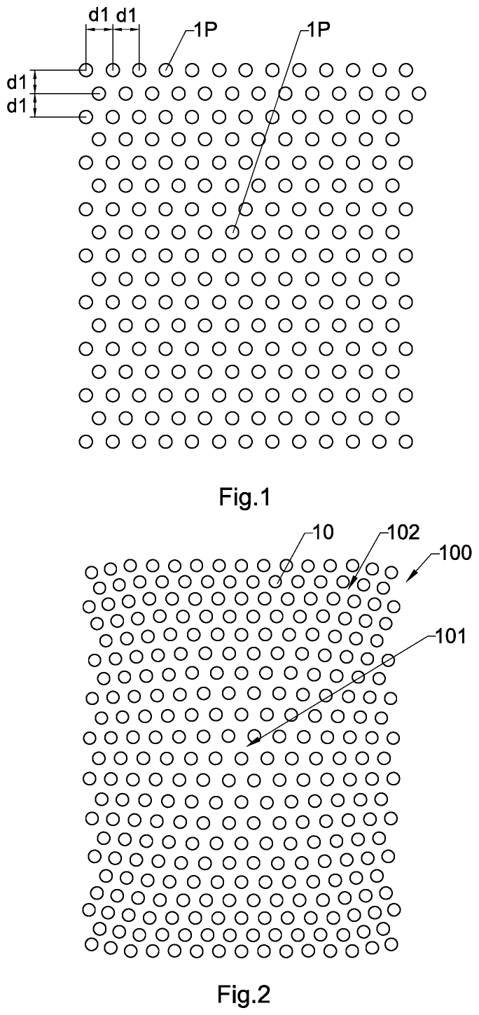

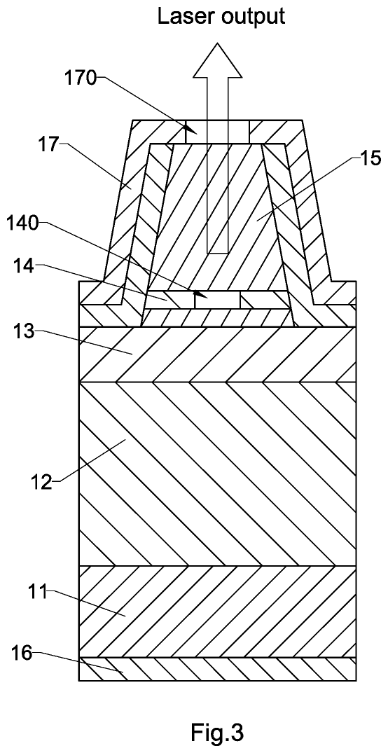

Referring to FIGS. 2 and 3 of the drawings, an VCSEL array 100 according to a first preferred embodiment of the present invention is illustrated. For applications that require uniform power output from all the elements across the array, the present invention is provided, that alleviate this problem, to increase spacing between the elements in the vicinity of the center areas of the array, and gradually decrease the spacing close to the edge, as shown in FIG. 2. However, it should be noted that changing element density (to maintain uniform power output from all elements) will not resolve nonuniform power density (optical power output per unit array area) problem, which is often more critical for illumination applications. However, according to the present invention, for array structures as shown in FIG. 2, power density will inevitably be lower in the center and higher close to the edge.

According to the preferred embodiment of the present invention, the VCSEL elements 10 of the VCSEL array 100 are arranged in a programmed pattern based on the optical output parameters, such a power distribution, wavelength, divergence, spectral width, speckle pattern, rise/fall-time, and etc. Particularly, the positions of the VCSEL elements 10 of the VCSEL array 100 according to the preferred embodiment is intentionally programmed to achieve a relatively better uniform overall power output compared with that of the conventional close-packed VCSEL array.

It is worth mentioning that the VCSEL units of the conventional VCSEL array, as shown in the FIG. 1 of the drawings, are arranged in a close-packed manner that each two of them has a fixed element-to-element spacing. Due to non-uniform heat dissipation for the VCSEL units in the center portion and those close to the peripheral edge portion, the temperate is higher in the vicinity of the center portion of the array and there is a temperate gradient descent from the center portion of the array to the peripheral edge thereof. Therefore, lower power output would be expected from those elements in the vicinity of the center portion of the array. In other words, the conventional VCSEL array fails to provide a uniform power output from all the VCSEL elements across the array.

As shown in the FIG. 2 of the drawings, the positions of the VCSEL elements 10 of the VCSEL array 100 according to the preferred embodiment of the present invention is re-arranged in the programmed pattern that the interval distances between the VCSEL elements 10 in a vicinity of a center portion 101 and/or at the center portion 101 are greater than the interval distances between the VCSEL elements 10 close to a peripheral edge portion 102, such that the VCSEL array 100 has a uniform power output. It is appreciated that the VCSEL elements 10 with a greater spacing have an enhanced performance in heat dissipating, and thus a temperate in the vicinity of the center portion 101 of the array 100 is decreased, such that the VCSEL array 100 is able to achieve a relatively better uniform overall power output compared with that of the conventional close-packed VCSEL array 100. As mentioned above, for applications that requires uniform power output from all the elements across the array 100, the preferred embodiment of the present invention provides one way to alleviate the conventional problem by increasing the interval distance between the elements 10 in the vicinity of the center portion 101 and/or at the center portion 101 of the array 100 and decreasing the interval distance close to the peripheral edge portion 102 thereof.

In some embodiments of the preferred embodiment, the interval distances between the VCSEL elements 10 are gradually decreased from the center portion 101 to the peripheral edge portion 102 of the VCSEL elements 10, in order to achieve a relatively better uniform overall power output.

According to the preferred embodiment of the present invention, the VCSEL elements 10 of the VCSEL array 100 generally have an interval distance between each two elements in the range of 18 microns to 200 microns (preferably 40 microns to 100 microns), while the interval distances between the VCSEL elements 10 in the vicinity of the center portion 101 and/or at the center portion 101 are greater than the interval distances between the VCSEL elements 10 close to the peripheral edge portion 102.

It is important to mention that the center portion 101 and the peripheral portion of the VCSEL elements 10 is defined and determined by the arrangement pattern of the VCSEL elements 10 instead of the geometry shape of the VCSEL array 100. Generally, the center portion 101 of the VCSEL elements 10 is defined at the center portion 101 of the VCSEL array 100, while the peripheral edge portion 102 of the VCSEL elements 10 is defined at the rim of the VCSEL array 100. Those skilled in the art would understand that the center portion 101 of the VCSEL elements 10 may not be defined at the geometry center portion 101 of the VCSEL array 100, and the peripheral edge portion 102 of the VCSEL elements 10 may not be defined at the geometry rim of the VCSEL array 100, which is not intended to be limiting in the present invention.

Referring to FIG. 3, an epitaxial structure of a VCSEL element 10 of the VCSEL array 100 according to the preferred embodiment of the present invention is illustrated, wherein the VCSEL element 10 is capable of emitting a predetermined number of lasers from the top side thereof. It is appreciated that other types of VCSEL element 10 may also be adopted in the present invention, such as the VCSEL element 10 which emits the laser from a bottom side.

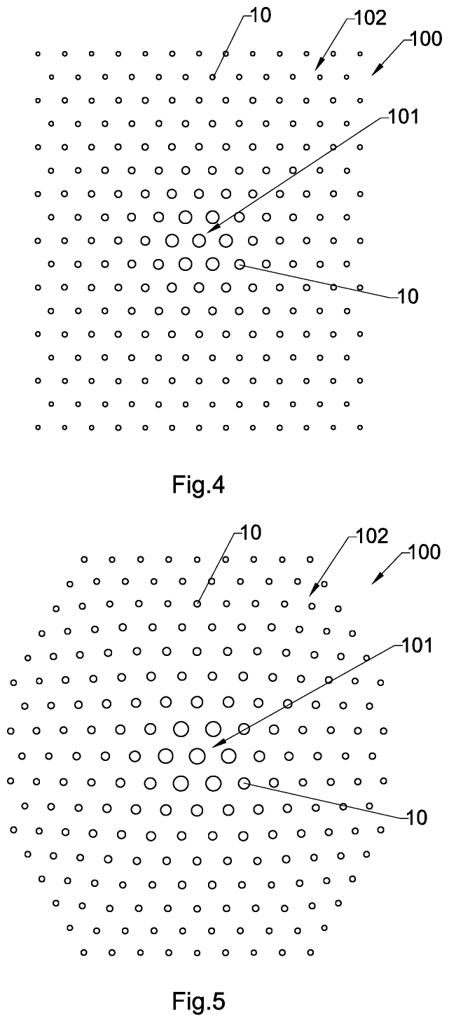

It is known that VCSEL emitters with different lateral confinement sizes usually have different power output. According to the present invention, by properly arranging elements with varying lateral confinement sizes across the array, as shown in FIG. 3, can pre-compensate the power density gradient from center to edges, while arrays with better performance may be obtained by combining structures as shown in FIG. 2 and FIG. 3, that is shown in FIG. 4.

More specifically, as shown in the FIG. 3, the VCSEL element 10 comprises a substrate 11, a first conducting layer 16 electrically connected to the substrate 11 at a bottom side thereof, a first metamorphic DBR 12 epitaxially formed on the substrate 11, at least one light emitting portion 13 epitaxially formed on the first metamorphic DBR 12, an oxide confining layer 14 which is formed on the at least one light emitting portion 13 and defines an oxide aperture 140, a second metamorphic DBR 15 formed on the oxide confining layer 14 while the at least one light emitting portion 13 is sandwiched between the first metamorphic DBR 12 and the second metamorphic DBR 15, and a second conducting layer 17 which is electrically connected to the second metamorphic DBR 15 and defines a light window 170 aligning with the oxide aperture 140 of the oxide confining layer 14.

In the preferred embodiment, a single light emitting region for simplicity and ease of discussion is embodied, wherein the substrate 11 includes indium phosphide (InP). However, it will be understood that the substrate 11 may include other materials, such as gallium arsenide (GaAs) or the like, which can be lattice matched with subsequent layer grown thereon.

The first metamorphic DBR 12 is epitaxially grown on the substrate 11. In the preferred embodiment, the first metamorphic DBR 12 comprises alternate layers of an AlxGa(1-x)As layer and a AlyGa(1-y)As layer (0.0<=x<=0.5, 0.5<=y<=1.0). However, it will be understood that the reflective layers can include other suitable reflective materials that are stacked alternatively between a high index of refraction and a low index of refraction. Further, according to the preferred embodiment, each of the reflective layers has a thickness approximately equal to one quarter of the wavelength of operation to provide a desired reflective property. Further, in the preferred embodiment, the first metamorphic DBR 12 is lightly doped N-type, namely, the first metamorphic DBR 12 is a N-type metamorphic DBR.

The light emitting portion 13, sandwiched between the first and second metamorphic DBRs 12, 15, comprises an active region with a plurality of quantum structure layers with a band gap wavelength, wherein each quantum structure layer substantially emits laser at the wavelength of operation. In the preferred embodiment, the quantum structure layers include quantum wells. However, it will be understood that the quantum structure layers may include other devices structure, such as quantum dots or similar device structures with suitable light emission properties.

The oxide confining layer 14 is stacked on the light emitting portion 13 and is formed during mesa process, wherein the oxide confining layer 14 has an oxide aperture 140 which acts as a current window, enabling the active region to be pumped more efficiently. Apart from this electrical property, the oxide aperture 140 can also have beneficial optical effects, counteracting diffraction and improving the modal stability of the oxide-confined VCSEL.

The second metamorphic DBR 15 is epitaxially grown on the light emitting portion 13. According to the preferred embodiment, the second metamorphic DBR 15 comprises alternate layers of a SiO layer and a TiO layer. However, it will be understood that the reflective layers can include other suitable reflective materials that are stacked alternately between a high index of refraction and a low index of refraction. Further, in the preferred embodiment, each of the reflective layers has a thickness approximately equal to one quarter of the wavelength of operation to provide a desired reflective property. Further, in the preferred embodiment, the second metamorphic DBR 15 is lightly doped P-type, namely, the second metamorphic DBR 15 is an P-type metamorphic DBR.

The first and second conducting layers 17 are electrically coupled to the second metamorphic DBR 15 and the substrate 11 respectively, wherein the first and second conducting layers 17 can include gold (Au), platinum (Pt), Silver (Ag), or the like. Further, in the preferred embodiment, the first conducting layer 16 serves as a negative electrode while the second conducting layer 17 serves as a positive electrode.

It is worth mentioning that the VCSEL elements 10 of the VCSEL array 100 may have a same epitaxial structure, i.e. the epitaxial structure as illustrated in the FIG. 3 of the drawing, such that the packaging for the VCSEL elements 10 of the VCSEL array 100 can be simplified. In other words, the VCSEL array 100 according to the preferred embodiment is capable of satisfying the uniform power output requirement with merely one single epitaxial structure. However, it will be understood that the VCSEL array 100 may adopt more than one epitaxial structure of the VCSEL element 10 in other certain examples.

In practice, the positions of the VCSEL elements 10 (especially the interval distance between each two of the VCSEL elements 10) can be pre-defined with thermal/electro-magnetic simulation software and then determined during wafer processing DOE (Design of Experiment).

It is also worth mentioning that other programmed pattern for the VCSEL elements 10 of the VCSEL array 100 may also be adopted in order to achieve a better uniform power output. For instance, the VCSEL array 100 may be arranged that each two of the VCSEL elements 10 have a fixed element-to-element interval distance therebetween, which is the similar to the conventional VCSEL array, but the output power for the those elements in the vicinity of the center portion and/or at the center portion 101 of the VCSEL elements 10 is greater than those close to the peripheral edge thereof, such that the greater output power of those elements in the vicinity of the center portion and/or at the center portion 101 of the VCSEL elements 10 compensate(s) the worse heat dissipation thereof in order to achieve a better uniform power output. It is well known that the VCSEL elements 10 with different lateral confinement sizes generally have different power outputs, and the VCSEL element 10 with a greater lateral confinement size typically has a larger power output. Also, the lateral confinement shape and size of the VCSEL element 10 may also be pre-defined with thermal/electro-magnetic simulation software.

Although by changing the positions and arrangement of the VCSEL elements 10 of the array 100 (namely by changing element density), the VCSEL array 100 is capable of maintaining a uniform power output from all the VCSEL elements 10, that is still unable to resolve the non-uniform power density issues. In other words, by arranging the VCSEL elements 10 in the programmed pattern as illustrated in the FIG. 2 of the drawings, the VCSEL array 100 is capable of achieving a better performance with a uniform overall power output, but it fails to provide a better performance in uniform power density which is often very critical for illumination applications. In particular, for the array 100 structures as shown in the FIG. 2, the power density will inevitably be lower in the center portion 101 and higher close to the peripheral edge portion 102.

Accordingly, the programmed pattern of the VCSEL elements 10 of the VCSEL array 100 should be modified in order to obtain a better in uniform power density according to a first alternative mode of the preferred embodiment as shown in the FIG. 4 of the drawing. As shown in the FIG. 4 of the drawings, the VCSEL elements 10 of the VCSEL array 100 is re-arranged in the programmed pattern that the interval distances between the VCSEL elements 10 is fixed and equal, while the VCSEL elements 10 positioned in the vicinity of the center portion 101 and/or at the center portion 101 of the VCSEL elements 10 have a greater power density than that of the VCSEL elements 10 close to the peripheral edge portion 102, such that the VCSEL array 100 has a uniform power density. In other words, in the first alternative mode of the preferred embodiment, the VCSEL array 100 has a fixed element-to-element interval distance between each two of VCSEL elements 10, while the elements in the vicinity of the center portion 101 and/or at the center portion 101 of the VCSEL elements 10 have a greater lateral confinement size that than that of the VCSEL elements 10 close to the peripheral edge portion 102, such that by arranging the VCSEL elements 10 with varying lateral confinement sizes across the array 100, as shown in the FIG. 4 of the drawings, the VCSEL array 100 is capable of pre-compensating the power density gradient from the center portion 101 of the VCSEL elements 10 to the peripheral edge portion 102 thereof.

It is important to mention that the VCSEL elements 10 of the VCSEL array 100 according to the preferred embodiment generally has an interval distance between each two elements in the range of 18 microns to 200 microns (preferably 40 microns to 100 microns). And, the VCSEL elements 10 of the VCSEL array 100 according to the preferred embodiment generally have a corresponding lateral confinement sizes in the range from 6 microns to 100 microns, preferably from 10 microns to 50 microns, while the elements in the vicinity of the center portion 101 and/or at the center portion 101 of the VCSEL elements 10 have a greater lateral confinement size that than that of the VCSEL elements 10 close to the peripheral edge portion 102.

In certain examples of the preferred embodiment, the output powers of the VCSEL elements 10 are gradually decreased from the center portion 101 of the VCSEL elements 10 to the peripheral edge portion 102 thereof. In other examples of the preferred embodiment, the lateral confinement sizes of the VCSEL elements 10 are gradually decreased from the center portion 101 of the VCSEL elements 10 to the peripheral edge portion 102 thereof.

It is worth mentioning that the programmed patterns of the VCSEL array 100 as illustrated in the FIG. 3 and FIG. 4 of the drawings can be combined together to obtain a better performance in both the overall optical power output and the optical power density across the array 100, as illustrated as a second alternative mode of the preferred embodiment as shown in the FIG. 5 of the drawings. More specifically, the VCSEL elements 10 of the array 100 is arranged in the programmed pattern that the interval distances between the VCSEL elements 10 in the vicinity of the center portion 101 and/or at the center portion 101 are greater than the interval distances between the VCSEL elements 10 close to the peripheral edge portion 102, while the elements in the vicinity of the center portion 101 and/or at the center portion 101 of the VCSEL elements 10 have a greater lateral confinement size that than that of the VCSEL elements 10 close to the peripheral edge portion 102, such that the VCSEL array 100 of the second alternative mode of the preferred embodiment is capable of achieving a better performance in both the overall optical power output and the optical power density across the array 100.

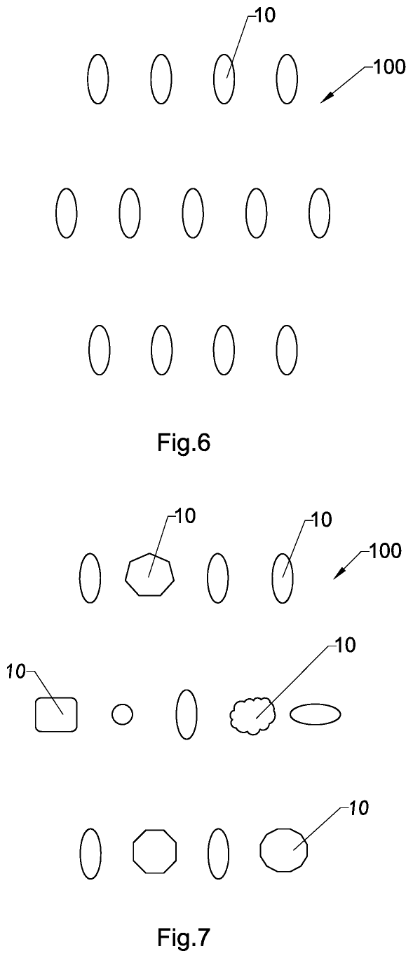

Referring to the FIG. 6 of the drawings, a third alternative mode of the preferred embodiment of the present invention is illustrated, wherein the VCSEL array 100 is illustrated as an alternative mode to improve optical output uniformity by configuring the VSCSEL elements in different lateral confinement shape. As shown in the FIG. 6 of the drawings, pre-compensated lateral confinement shapes of the VCSEL elements 10 of the array 100 are programmed to resolve current crowding issues at the current confinement layer (namely the oxide confining layer 14).

According to a fourth alternative mode of the preferred embodiment, as shown in FIG. 7 of the drawings, the VCSEL elements 10 of the array 100 have an elliptical shape in order to resolve current crowding issues. It is worth mentioning that the lateral confinement shape of the VCSEL elements 10 includes, but is not limited to, regular shape (circular shape) and irregular shapes such as ellipse, rectangle, hexagon and etc.

It is appreciated that a better uniformity optical output parameters can be achieved by arranging the VCSEL elements 10 with appropriate confinement sizes and shapes in appropriate positions based on the distribution requirements on power, wavelength, divergence, and etc., as illustrated in the FIG. 2, and FIG. 3 to FIG. 7 of the preferred embodiment. It is worth mentioning that better non-uniformity issues related to other optical parameters such as divergence and rise/fall-time can also be engineered using similar structures as shown in the FIG. 2, and FIG. 3 to FIG. 7 of the drawings. For example, FIG. 8 illustrates a fifth alternative mode of the preferred embodiment of the present invention, wherein the VCSEL elements 10 of the array 100 are arranged in a specific pattern that the longitudinal interval distance between the VCSEL elements 10 is greater than the transverse interval distance between the VCSEL elements 10, in order to obtain a greater optical divergence between the longitudinal direction and the transverse direction across the array 100.

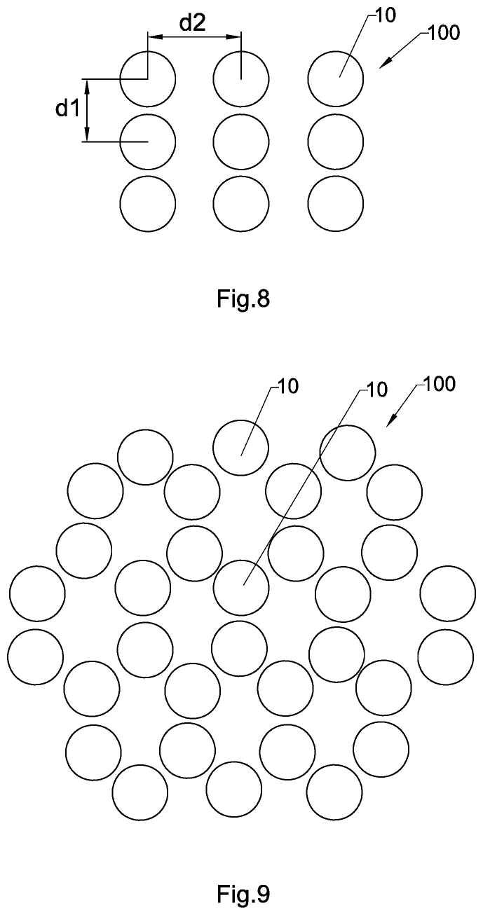

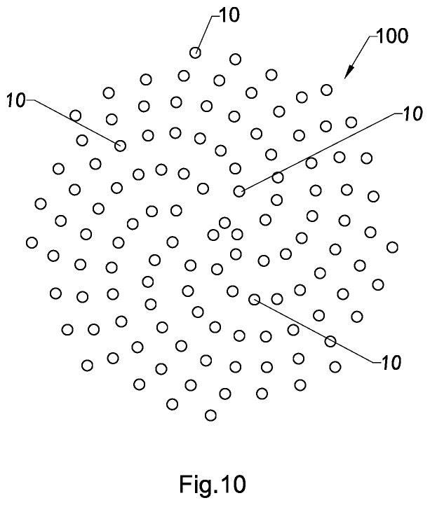

Also, the VCSEL elements 10 of the VCSEL array 100 can be arranged in specific manners in accordance with the optical requirements of the corresponding application scenarios, such as the spiral patterns as illustrated in the sixth and seventh alternative modes of the preferred embodiment as shown in the FIG. 9 and FIG. 10 of the drawings.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An output-programmed VCSEL array, comprising a plurality of VCSEL elements arranged in a programmed pattern defining a center portion and a peripheral edge portion, wherein interval distances between the VCSEL elements, in a position selected from the group consisting of in a vicinity of the center portion, at the center portion, and in the vicinity of the center portion and at the center portion, are greater than interval distances between the VCSEL elements close to the peripheral edge portion, so as to provide a uniform overall power output.

2. The output-programmed VCSEL array, as recited in claim 1, wherein the interval distances between the VCSEL elements are gradually decreased from the center portion to the peripheral edge portion of the VCSEL elements.

3. The output-programmed VCSEL array, as recited in claim 1, wherein the VCSEL elements positioned in a position, selected from the group consisting of in the vicinity of the center portion, at the center portion, and in the vicinity of the center portion and at the center portion, of the VCSEL elements have a greater power output than that of the VCSEL elements close to the peripheral edge portion, so as to provide a uniform power density.

4. The output-programmed VCSEL array, as recited in claim 3, wherein the output power of the VCSEL elements of the VCSEL array is gradually decreased from the center portion to the peripheral edge portion.

5. The output-programmed VCSEL array, as recited in claim 3, wherein lateral confinement sizes of the VCSEL elements in the vicinity of the center portion of the VCSEL elements are greater than that of the VCSEL elements close to the peripheral edge portion thereof, so as to provide a uniform power density.

6. The output-programmed VCSEL array, as recited in claim 5, wherein the lateral confinement sizes of the VCSEL elements are gradually decreased from the center portion of the VCSEL elements to the peripheral edge portion thereof.

7. The output-programmed VCSEL array, as recited in claim 1, wherein the center portion of the VCSEL elements is defined at a geometry center portion of the VCSEL array, while the peripheral edge portion of the VCSEL elements is defined at the geometry peripheral edge portion of the VCSEL array.

8. The output-programmed VCSEL array, as recited in claim 3, wherein the center portion of the VCSEL elements is defined at a geometry center portion of the VCSEL array, while the peripheral edge portion of the VCSEL elements is defined at the geometry peripheral edge portion of the VCSEL array.

9. The output-programmed VCSEL array, as recited in claim 5, wherein the center portion of the VCSEL elements is defined at a geometry center portion of the VCSEL array, while the peripheral edge portion of the VCSEL elements is defined at the geometry peripheral edge portion of the VCSEL array.

10. The output-programmed VCSEL array, as recited in claim 1, wherein each of the VCSEL elements has a circular lateral confinement shape.

11. The output-programmed VCSEL array, as recited in claim 1, wherein each of the VCSEL elements has an elliptical lateral confinement shape.

12. The output-programmed VCSEL array, as recited in claim 1, wherein each of the VCSEL elements has non-circular lateral confinement shape.

13. The output-programmed VCSEL array, as recited in claim 1, wherein the interval distance between each two of the VCSEL elements is ranged from 18 microns to 200 microns.

14. The output-programmed VCSEL array, as recited in claim 5, wherein the interval distance between each two of the VCSEL elements is ranged from 18 microns to 200 microns.

15. The output-programmed VCSEL array, as recited in claim 1, wherein the lateral confinement sizes of the VCSEL elements are ranged from 6 microns to 100 microns.

16. The output-programmed VCSEL array, as recited in claim 14, wherein the lateral confinement sizes of the VCSEL elements are ranged from 6 microns to 100 microns.

17. The output-programmed VCSEL array, as recited in claim 16, wherein each of the VCSEL elements comprises a substrate, a first conducting layer electrically connected to substrate at the bottom side thereof, a first metamorphic DBR epitaxially formed on the substrate, at least one light emitting portion epitaxially formed on the first metamorphic DBR, an oxide confining layer which is formed on the at least one light emitting portion and defines an oxide aperture, a second metamorphic DBR formed on the oxide confining layer, wherein the at least one light emitting portion is sandwiched between the first metamorphic DBR and the second metamorphic DBR, and a second conducting layer is electrically connected to the second metamorphic DBR and defines a light window aligning with the oxide aperture of the oxide confining layer.

18. An output-programmed VCSEL array, comprising a plurality of VCSEL elements arranged in a programmed pattern defining a center portion and a peripheral edge portion, wherein the VCSEL elements, positioned in a position selected from the group consisting of in a vicinity of the center portion, at the center portion of the VCSEL elements and in the vicinity of the center portion and at the center portion of the VCSEL elements, have a greater power output than that of the VCSEL elements close to the peripheral edge portion, so as to provide a uniform power density.

19. The output-programmed VCSEL array, as recited in claim 18, wherein output powers of the VCSEL elements of the VCSEL array are gradually decreased from the center portion to the peripheral edge portion.

20. The output-programmed VCSEL array, as recited in claim 18, wherein lateral confinement sizes of the VCSEL elements are ranged from 6 microns to 100 microns.
